(19) United States
(12) Patent Application Publication
(10) Pub. No.: US 2017/0253963 A1
(43) Pub. Date: Sep. 7, 2017

(54) Method of Efficient Coaxial Delivery of Microwaves into a Mode Stabilized Resonating Chamber for the Purpose of Deposition of Microwave Plasma CVD Polycrystalline Diamond Films

(71) Applicant: II-VI Incorporated, Saxonburg, PA (US)

(72) Inventors: David Sabens, Harmony, PA (US); Elgin E. Eissler, Renfrew, PA (US)

(21) Appl. No.: 15/444,772

(22) Filed: Feb. 28, 2017

Related U.S. Application Data
(60) Provisional application No. 62/302,883, filed on Mar. 3, 2016.

(51) Int. Cl. C23C 16/27; H01J 37/32

(52) U.S. Cl. CPC C23C 16/274; H01J 37/3222; H01J 37/32238; H01J 37/32247; H01J 37/32256; H01J 2237/3321

(57) ABSTRACT

Disclosed is a chemical vapor deposition (CVD) reactor includes a resonating cavity configured to receive microwaves. A microwave transparent window is disposed in the resonating cavity, intermediate a top and bottom of the resonating cavity, separating the resonating cavity into an upper zone and a plasma zone. The resonating cavity is configured to propagate microwaves from the upper zone through the microwave transparent window into the plasma zone. A noise cancelling antenna is disposed in a non-weight bearing manner through an opening in the microwave transparent window. Also disclosed is a method that includes (a) providing the above-described CVD reactor; (b) feeding a carbon bearing reactive gas into the plasma zone; and (c) concurrent with step (b), feeding microwaves into the resonant cavity thereby forming in the plasma zone a plasma that causes a diamond film to form in the plasma zone.

### CROSS REFERENCE TO RELATED APPLICATION

This application claims the benefit of U.S. Provisional Application 62/302,883, filed Mar. 3, 2016, the contents of which are incorporated herein in its entirety by reference.

### BACKGROUND OF THE INVENTION

Field of the Invention

The present invention relates to a microwave plasma CVD reactor and, more particularly, to means for coaxial delivery of microwaves into a mode stabilized resonating chamber of the microwave plasma CVD reactor.

Description of Related Art

Polycrystalline diamond films have long been recognized for their unique combination of optical properties. Its low absorption of 10.6 um and 1 um wavelengths makes it an ideal material for use in windows transparent to a range of wavelengths with applications such as advanced photolithographic patterning techniques. In addition to UV transparency, polycrystalline diamond films have extraordinarily high thermal conductivity (sometimes exceeding 2000 W/mK), low thermal expansion coefficient, microwave transparency, and extreme hardness. These properties and more make it a very valuable material for a variety of applications.

Presently, polycrystalline diamond films are grown on the industrial scale using a technique called Chemical Vapor Deposition (CVD). Examples of CVD reactors for diamond include: hot filament, DC arc jet, flame, and microwave plasma.

To achieve the highest quality diamond in terms of optical, microwave and nuclear detector performance, microwave plasma CVD (MPCVD) is commonly employed. For Microwave Plasma CVD growth, a substrate (typically made of W, Mo or Si) is loaded into the bottom of the growth chamber. A microwave plasma is generated within the growth chamber flowing a reactive gas mixture of H₂ with ˜0.1-5% CH₄. The substrate is heated to a temperature generally ranging from ˜700-1200 C at a pressure of ˜10-250 Torr. Within this range of conditions, diamond is a metastable material that, due to differences in density, is preferentially deposited over graphite. The microwave plasma generates chemical precursors necessary for diamond deposition reactions to take place on the substrate surface.

In order to do this with the high degree of consistency and repeatability necessary for a production level process, microwaves need to be effectively delivered into the resonant chamber. In addition, to aid in coupling of a desired eigenmode, it is desirable to shift the resonant frequency of a chamber towards the incident wave's frequency.

It would, therefore, be desirable to provide means to efficiently transition microwaves propagating in a rectangular waveguide to a highly uniform propagation within a coaxial waveguide, reducing the coaxial length required for highly uniform microwave delivery; to isolate the diamond growth space from the remainder of the resonating chamber while tightly controlling the resonant frequency of the entire resonating chamber; and eliminate parasitic plasmas within the resonating growth chamber; ensuring the coupled power is being used to sustain the diamond growth reactions.

### SUMMARY OF THE INVENTION

Disclosed herein is/are means for efficient coaxial delivery of microwaves into a mode stabilized resonating chamber of a MPCVD reactor for the purpose of growing MPCVD polycrystalline diamond films. The means can include one or more of three features described below. These features are useful across all microwave spectrums and simply scale with microwave wavelength.

(1) Transitional stabilization rings within a coaxial waveguide: Immediately downstream of a rectangular to cylindrical coaxial waveguide transition is provided a short length of coaxial waveguide wherein the microwave propagation is unstable. The addition of apertures within this transitional region centers and stabilizes the microwave flow. This allows for more uniform microwave distribution in the MPCVD reaction zone resulting in more uniform growth rates and stress profiles in the resultant MPCVD polycrystalline diamond film.

(2) Mode Stabilizing Annular Window: A self-supporting annular window bisects the microwave resonating chamber, separating the diamond growth space from the remaining portion of the chamber. Its outer radius and thickness can be varied based on other chamber parameters to shift the desired resonant eigenmode to the target wavelength of the incident microwaves. On an outer edge of the self-supporting annular window, a face seal is formed with the upper and lower chamber portions. An inner ring of the annular window is sealed against a suspended antenna structure discussed next. No additional cross supports are needed for this design.

(3) Suspended, node-cancelling, coaxial antenna: A coaxial microwave waveguide whose central element seamlessly transitions into an antenna, delivering microwaves into the MPCVD reaction space. The base of the antenna can be shaped to the contours of the electric field within the MPCVD portion of the resonating chamber. By doing this, the resonant frequency of the chamber remains similar to a system where the antenna is absent while eliminating a region of high intensity electric field present at the top of the lower portion of the resonant chamber, thus eliminating the potential for parasitic plasmas to form. The antenna maintains a vacuum seal with the annular window described above. The antenna/central coax travels through the rectangular waveguide/coaxial waveguide transition and outside of the microwave delivery system. The protrusion outside of the waveguide system is threaded and is suspended using a bolt. In addition, cooling fluid, e.g., water and/or gasses, used in the diamond growth can optically be delivered through this protrusion.

### BRIEF DESCRIPTION OF THE DRAWINGS

FIG. 1 is a cross section of an MPCVD reactor including a resonating chamber (divided into a lower plasma zone and an upper zone by an annular window), a coaxial waveguide, and a rectangular waveguide;

FIG. 2 is a chart of computed variance of the electric field on a fixed radius vs position along the coaxial waveguide, wherein computed variance =standard deviation of a set of values divided by the average of the same set of values;

FIG. 3 is a chart illustrating the impact of the diameter and thickness of the annular window on the resonant frequency of a given eigenmode within the resonant chamber; and

FIGS. 4A-4B are respective electric field contour plots within the plasma zone of the resonating chamber for an MPCVD reactor without a suspended, node-cancelling, coaxial antenna installed (FIG. 4A) and an MPCVD reactor with a suspended, node-cancelling, coaxial antenna installed (FIG. 4B).

### DESCRIPTION OF THE INVENTION

The following examples will be described with reference to the accompanying figures where like reference numbers correspond to like or functionally equivalent elements.

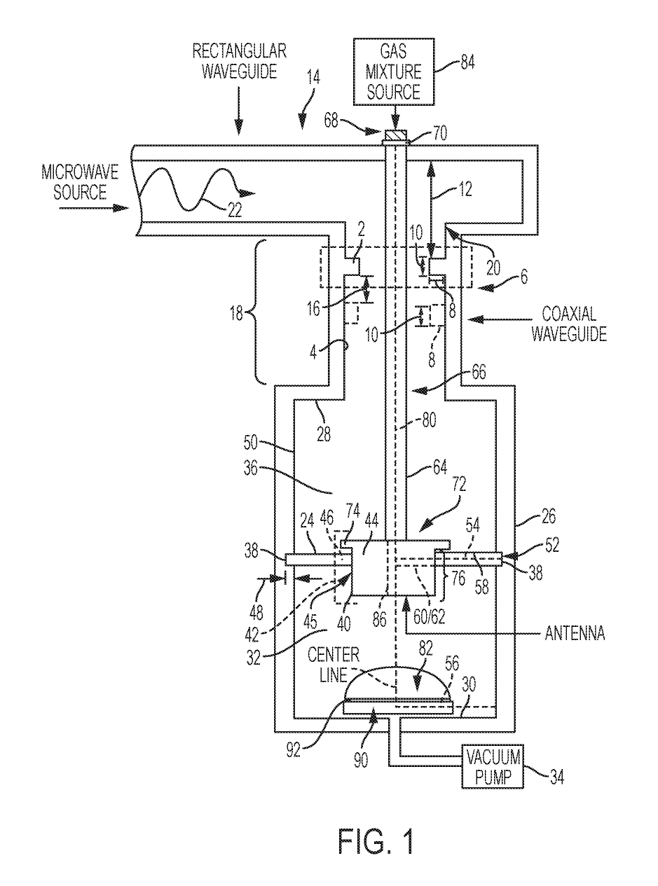

Transitional stabilization rings within a coaxial waveguide: Referring to the MPCVD reactor shown in FIG. 1, a coaxial waveguide 6 includes a protrusion or ring 2 that extends inwardly from an inner wall 4 of the coaxial waveguide 6. Ring 2 has a depth of 8, a height of 10, and is positioned a distance 12 of 3/4λ from a top inside wall of a rectangular waveguide 14. If multiple rings 2 are desired to increase stability, a distance 16 between adjacent pairs of rings 2, from the bottom side of the top one of the pair of rings 2 to the top side of the bottom one of the pair of rings 2, can be 1/2λ (as shown in FIG. 1). In an example, in a MPCVD reactor designed to operate at 915 MHz, distance 12 can be 225 mm±10 mm, depth 8 can be 24 mm±1.5 mm, height 10 can be 20 mm±1 mm, and distance 16 can be 160 mm±8 mm. These values varying±some value depend on the design of the MPCVD reactor and the exact value for each distance can be obtained via optimization in modeling software.

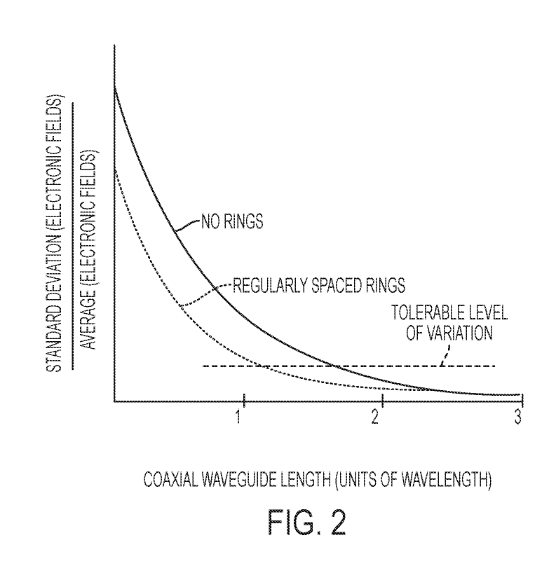

FIG. 2 compares how quickly the electric field becomes uniform as a function of coaxial waveguide 6 length 18 for two situations: (1) a coaxial waveguide 6 with one or more regularly spaced rings or protrusions 2 as shown in FIGS. 1 and (2) a coaxial waveguide 6 with no rings or protrusions 2. In FIG. 2, the y-axis represents a computed variance of the electric field at a fixed radius along the length of coaxial waveguide 6, and the x-axis represents the length 18 of coaxial waveguide 6 where x=0 is a transition 20 between rectangular waveguide 14 and coaxial waveguide 6.

In FIG. 2, two lines are plotted. One for coaxial waveguide 6 having one or more protrusions or rings 2 installed (“Regularly Spaced Rings”) and one without protrusion or rings 2 installed (“No Rings”). As can be seen from FIG. 2, as microwaves travel down the length of coaxial waveguide 6, the use of one or more protrusions or rings 2 achieves a low value of computed variance about one-half of one wavelength sooner than without protrusions or rings 2. Stated differently, a tolerable level of computed variation (shown, e.g., by the dashed line in FIG. 2) is achieved one-half wavelength sooner when one or more protrusions or rings 2 are added.

For microwaves 22 at a frequency of 915 MHz, a tolerable level of computed variation (shown by the dashed line in FIG. 2) is achieved one-half wavelength sooner when one or more rings 2 are present. This one-half wavelength is equivalent to 164 mm, meaning that coaxial waveguide 6 including one or more rings 2 can have a length 18 that is 164 mm shorter than a coaxial waveguide that does not have one or more rings 2 for the same computed variance.

This example for microwaves 22 at a frequency of 915 MHz is not to be construed in a limiting sense since microwaves at different frequencies can result in rings 2 of different height 10, depth 8, distance 12, distance 16 (if applicable), and length 18.

Mode Stabilizing Annular Window: Referring back to FIG. 1, a microwave transparent, annular window 24, made of quartz for example, can be placed in resonating chamber or cavity 26 of the MPCVD reactor, which, in an example, can have a tubular inner wall 50 along the axial length of resonating chamber or cavity 26, intermediate a top 28 and a bottom 30 of resonating cavity 26, in an example, in the middle of resonating cavity 26. This window 24 can act as a physical barrier between a low-pressure plasma zone 32 (evacuated via a vacuum pump 34) required for MPCVD processing and an upper zone 36 of resonating cavity 26 which, in an example, can be at atmospheric pressure. At its outer edge, annular window 24 can be received in an annular recess 52 of an inner wall 50 of resonating cavity 26 and is sealed to resonating cavity 26 via an O-ring 38. On its inner edge, annular window 24 is sealed to an outer wall 40 of a head 42 of a suspended, node-cancelling, coaxial antenna 44 via another O-ring 46. Antenna 44 does not rest on annular window 24, whereupon annular window 24 does not bear the weight of antenna 44. The means by which antenna 44 is suspended in a non-weight bearing manner through an opening 45 in annular window 44 is discussed hereinafter.

In practice, resonating cavity 26 is two separate zones, namely, plasma zone 32 below annular window 24 and upper zone 36 above annular window 24, which are split at the location of annular window 24. Annular window 24 has an outer diameter that can extend a distance 48 past the inner wall 50 of resonating cavity 26, in an example, into annular recess 52 in the inner wall 50 of resonating cavity 26. This distance 48 can be selected by one skilled in the art to aid in the tuning of resonant modes within resonating cavity 26.

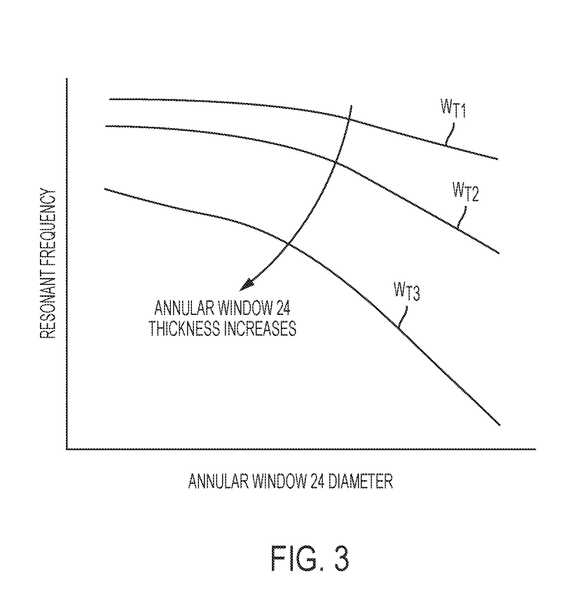

FIG. 3 illustrates the impact of window 24 thickness and outer diameter on the resonant frequency of a desired eigenmode within resonating cavity 26. In an example, window 24 can be sufficiently thick to withstand the forces from the pressure differential between plasma zone 32 and upper zone 36 of resonating cavity 26. This thickness can provide a broad range of control of a particular eigenmode' s resonant frequency from 100 to 250 MHz. The thickness of window 24 can also be based on other aspects of the MPCVD reactor such as, for example, cavity 26 size and shape as well as any additional elements that can be installed within cavity 26 to control and select particular eigenmodes. In an example, window 24 has an outer radius 54 of 100%-115% of the resonating cavity 26 radius 56 and a thickness 58 of 6-15% of the resonating cavity 26 radius 56. The radius 60 of the outer wall 40 of the head 42 of antenna 44 can be equal to the radius 62 of the head 42 of antenna 44 with compensation for the O-ring 46 seal with window 24. As the thickness 58 of window 24 increases, the resonant frequency of cavity 26 falls or decreases based on the trends shown in FIG. 3.

As can be seen in FIG. 3, annular window Wt₃ is thicker than annular window Wt₂ which is thicker than annular window Wt₁. As FIG. 3 illustrates, increasing either the annular window 24 thickness or diameter forces a reduction in a given eigenmode' s resonant frequency.

Suspended, node-cancelling, coaxial antenna 44: An inner shaft 64 of a conductive coaxial portion 66 of coaxial waveguide 6 extends from coaxial antenna 44 upwardly through the rectangular waveguide 14/coaxial waveguide 6 transition 20 and through an upper wall of rectangular waveguide 14. A part 68 of the conductive coaxial portion 66 of coaxial waveguide 6 that extends outside of (above in FIG. 1) rectangular waveguide 14 is threaded and a securing bolt 70 is used to suspend antenna 44 and control its position within resonating cavity 26. Coaxial waveguide 6 is coupled to and transitions into antenna 44 in upper zone 36 of resonating cavity 26.

At annular window 24, antenna 44 bulges out from inner shaft 64 into the head 72 of antenna 44. Head 72 includes a wider disk portion 74 above a body portion 76 of antenna 44, which body portion 76 passes through opening 45 in annular window 24. Disk portion 74 is an aid for concentric positioning of coaxial antenna 44 and inner wall 50 of resonating cavity 26 and, more particularly, is an aid for concentric positioning of body portion 76 of coaxial antenna 44 and inner wall 50 of resonating cavity 26. This can be accomplished by inserting feeler gauges (not shown) between disk portion 74 and annular window 24 to ensure that antenna 44 is perpendicular to window 24 and coaxial to the inner wall 50 of resonating cavity 26.

In an example, an interior of inner shaft 64 can be hollow and can be used to feed a reactive gas mixture 80 used to form plasma 82 (in a manner known in the art in response to excitation with microwaves 22) from a reactive gas source 84 into plasma zone 32 via head 42 of antenna 44. In an example, the reactive gas mixture 80 can be fed into plasma zone 32 via a duct or conduit 86 in head 42 of antenna 44, which conduit 86 is in fluid communication with the interior of shaft 64.

The bottom end of inner shaft 64 can be coupled to the top central part of disk portion 74 (as shown in FIG. 1) in any suitable and/or desirable manner.

The body portion 76 of head 42 of antenna 44 that extends through annular window 24 acts as a virtual microwave choke by minimizing the electric field adjacent annular window 24 inside plasma zone 32.

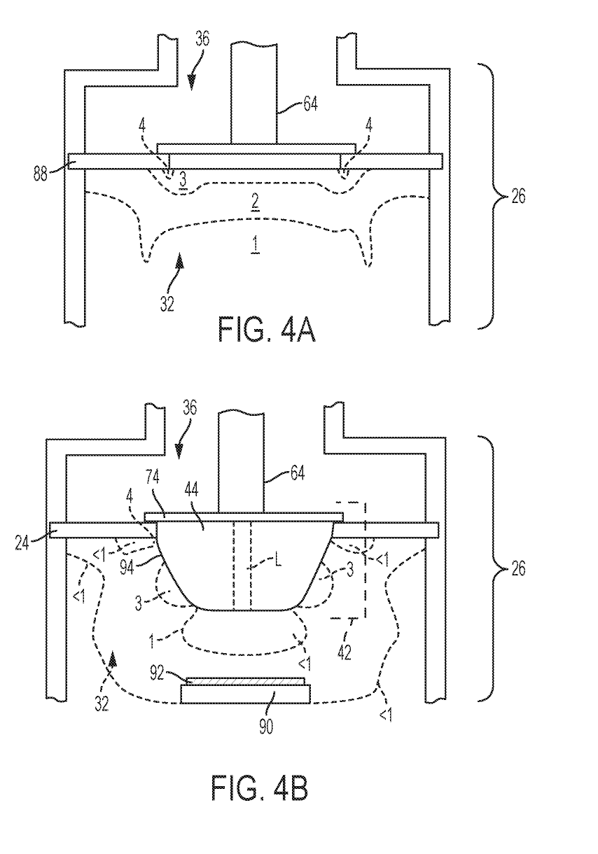

FIGS. 4A-4B shows a comparison of contour plots of electric fields within plasma zone 32 of identical systems with (FIG. 4B) and without (FIG. 4A) the node-cancelling, coaxial antenna 44 using relative numbers, where the greater the relative number equates to a more intense electric field.

FIG. 4A illustrates a resonating cavity 26 without the node-cancelling, coaxial antenna 44. At its most intense, the electric field against the annular window 24 in FIG. 4A is 3-4 times more intense than the most intense electric field against window 24 in FIG. 4B with the node-cancelling, coaxial antenna 44 installed. This translates to more efficient coupling of plasma 82 above a substrate 90 where MPCVD plasma growth of a diamond film 92 occurs and a dramatically longer lifetime of annular window 24 by avoiding or eliminating parasitic plasmas forming at window 24.

In addition to cancelling the high intensity node at annular window 24, the head 42 of the suspended, node-cancelling, coaxial antenna 44 can be shaped to influence the shape of the resonant electric field. In an example, shown in FIG. 4B, the side 94 of antenna 44 can taper inwardly toward substrate 90 to provide uniform electric field distribution above the diamond growth surface of substrate 90, resulting in more uniform growth of diamond film 92 and more uniform stress profiles within diamond film 92. Stated differently, the side 94 of antenna 44 can converge away from annular window 24.

In a method of growing diamond film 92 on substrate 90, vacuum pump 34 evacuates plasma zone 32 while, simultaneously, a carbon-bearing reactive gas mixture 80 is introduced into plasma zone 32 via the interior of inner shaft 64 and conduit 86 of coaxial antenna 44. The operation of vacuum pump 34 and the flow of a reactive gas mixture 80 into plasma zone 32 is controlled so that plasma zone 32 is at a suitable pressure for the growth of diamond film 92 on substrate 90. At a suitable time after appropriate growth conditions have been established in plasma zone 32 by vacuum pump 34 and the flow of reactive gas mixture 80 into plasma zone 32, a microwave source introduces microwaves 22 into rectangular waveguide 14. The microwaves 22 introduced into rectangular waveguide 14 propagate through coaxial waveguide 6 into resonating cavity 26. In resonating cavity 26, the microwaves 22 propagate initially through upper zone 36 and then through annular window 24 into plasma zone 32. In plasma zone 32, the microwaves 22 react with the reactive gas mixture 80 to produce plasma 82, which causes a growth of diamond film 92 on substrate 90 in a manner known in the art.

As can be seen, disclosed herein is a chemical vapor deposition (CVD) reactor comprising: a resonating cavity configured to receive microwaves; a microwave transparent window disposed in the resonating cavity separating the resonating cavity into an upper zone and a plasma zone, wherein the resonating cavity is configured to propagate microwaves from the upper zone through the microwave transparent window into the plasma zone; and an antenna disposed in a non-weight bearing manner through an opening in the microwave transparent window.

The CVD reactor can include a coaxial waveguide configured to feed the microwaves into the upper zone of the resonating cavity.

The CVD reactor can include a rectangular waveguide configured to feed the microwaves from a microwave source to the coaxial waveguide.

The CVD reactor can include a first ring protruding inwardly from an inner wall of the coaxial waveguide.

The CVD reactor can include a rectangular waveguide configured to feed the microwaves from a microwave source to the coaxial waveguide, wherein a distance between the first ring and a top, inside wall of the rectangular waveguide is 0.75λ, where λ is a wavelength of the microwaves at which the CVD reactor is designed to operate.

The first ring can protrude inwardly from the inner wall of the coaxial waveguide a distance 24 mm±1.5 mm. The first ring can have a height of 20 mm±1 mm in a propagation direction of the microwaves in the coaxial waveguide.

The CVD reactor can include a second ring protruding inwardly from the inner wall of the coaxial waveguide. The first and second rings can be spaced from each other in a propagation direction of the microwaves in the coaxial waveguide. The spacing can be a distance of 0.5k, where λ is a wavelength of the microwaves at which the CVD reactor is designed to operate.

The coaxial waveguide can include a conductive coaxial portion extending coaxially with an inner wall of the coaxial waveguide. The conductive coaxial portion can support the antenna in the non-weight bearing manner through the opening in the microwave transparent window.

The conductive coaxial portion can include a hollow interior in fluid communication with the plasma zone via a conduit in the antenna. The hollow interior of the conductive coaxial portion and the conduit in the antenna can be used to feed a reactive gas mixture from a reactive gas mixture source into the plasma zone.

The antenna can include a body portion disposed through the opening of the microwave transparent window. The body portion of the antenna and the opening can have circular shapes.

The antenna can include a disk portion positioned in the upper zone of the resonating chamber. The body portion of the antenna can have a first diameter. The disk portion can have a second diameter that is greater than the first diameter.

A side of the body portion of the antenna can converge away from the microwave transparent window.

An inner wall of the coaxial waveguide can have a first diameter. An inner wall of the resonating cavity can have a second diameter. The second diameter can be greater than the first diameter.

A conductive coaxial portion of the coaxial waveguide can support the weight of the antenna.

A first end the conductive coaxial portion of the coaxial waveguide can be coupled to the antenna. A second end of the conductive coaxial portion can be supported by a rectangular waveguide that is configured to feed the microwaves from a microwave source into the coaxial waveguide.

A vacuum pump can be provided for evacuating the plasma zone to a pressure where a plasma can form in the plasma zone in response to the presence of a reactive gas and the microwaves in the plasma zone.

The antenna can include a body portion that extends into the plasma zone from the microwave transparent window. An electric field that can form against the microwave transparent window in the plasma zone by the antenna can be 3-4 less intense over the electric field that would form in the absence of the body portion.

Also disclosed is a method of CVD reactor operation comprising: (a) providing the CVD reactor of claim 1; (b) feeding a carbon bearing reactive gas into the plasma zone; and (c) concurrent with step (b), feeding microwaves into the resonant cavity thereby forming in the plasma zone a plasma that causes a diamond film to form in the plasma zone.

The method can further include: (d) concurrent with step (c), evacuating the plasma zone to a pressure lower than the upper zone.

In practice of the method, the diamond film can form on a substrate disposed on a side of the plasma zone opposite the antenna.

The examples have been described with reference to the accompanying figures. Modifications and alterations will occur to others upon reading and understanding the foregoing examples. Accordingly, the foregoing examples are not to be construed as limiting the disclosure.

1. A chemical vapor deposition (CVD) reactor comprising:
a resonating cavity configured to receive microwaves;
a microwave transparent window disposed in the resonating cavity separating the resonating cavity into an upper zone and a plasma zone, wherein the resonating cavity is configured to propagate microwaves from the upper zone through the microwave transparent window into the plasma zone; and
an antenna disposed in a non-weight bearing manner through an opening in the microwave transparent window.

2. The CVD reactor of claim 1, further including a coaxial waveguide configured to feed the microwaves into the upper zone of the resonating cavity.

3. The CVD reactor of claim 2, further including a rectangular waveguide configured to feed the microwaves from a microwave source to the coaxial waveguide.

4. The CVD reactor of claim 2, further including a first ring protruding inwardly from an inner wall of the coaxial waveguide.

5. The CVD reactor of claim 4, further including a rectangular waveguide configured to feed the microwaves from a microwave source to the coaxial waveguide, wherein a distance between the first ring and a top, inside wall of the rectangular waveguide is 0.75λ, where λ is a wavelength of the microwaves at which the CVD reactor is designed to operate.

6. The CVD reactor of claim 4, wherein the first ring:
protrudes inwardly from the inner wall of the coaxial waveguide a distance 24 mm±1.5 mm; and
has a height of 20 mm±1 mm in a propagation direction of the microwaves in the coaxial waveguide.

7. The CVD reactor of claim 4, further including a second ring protruding inwardly from the inner wall of the coaxial waveguide, wherein the first and second rings are spaced from each other in a propagation direction of the microwaves in the coaxial waveguide a distance of 0.5λ, where λ is a wavelength of the microwaves at which the CVD reactor is designed to operate.

8. The CVD reactor of claim 2, wherein:
the coaxial waveguide includes a conductive coaxial portion extending coaxially with an inner wall of the coaxial waveguide; and
the conductive coaxial portion supports the antenna in the non-weight bearing manner through the opening in the microwave transparent window.

9. The CVD reactor of claim 7, wherein the conductive coaxial portion includes a hollow interior in fluid communication with the plasma zone via a conduit in the antenna, the hollow interior of the conductive coaxial portion and the conduit in the antenna configured to feed a reactive gas from a reactive gas source into the plasma zone.

10. The CVD reactor of claim 1, wherein:
the antenna includes a body portion disposed through the opening of the microwave transparent window; and
the body portion of the antenna and the opening have circular shapes.

11. The CVD reactor of claim 10, wherein:
the antenna includes a disk portion positioned in the upper zone of the resonating chamber;
the body portion of the antenna has a first diameter; and
the disk portion has a second diameter that is greater than the first diameter.

12. The CVD reactor of claim 11, wherein a side of the body portion of the antenna converges away from the microwave transparent window.

13. The CVD reactor of claim 2, wherein:
an inner wall of the coaxial waveguide has a first diameter;
an inner wall of the resonating cavity has a second diameter; and
the second diameter is greater than the first diameter.

14. The CVD reactor of claim 2, wherein a conductive coaxial portion of the coaxial waveguide supports the weight of the antenna.

15. The CVD reactor of claim 14, wherein:
a first end the conductive coaxial portion of the coaxial waveguide is coupled to the antenna; and
a second end of the conductive coaxial portion is supported by a rectangular waveguide that is configured to feed the microwaves from a microwave source into the coaxial waveguide.

16. The CVD reactor of claim 1, further including a vacuum pump configured to evacuate the plasma zone to a pressure where a plasma forms in the plasma zone in response to the presence of a reactive gas and the microwaves in the plasma zone.

17. The CVD reactor of claim 16, wherein:
the antenna includes a body portion that extends into the plasma zone from the microwave transparent window; and
an electric field formed against the microwave transparent window in the plasma zone by the antenna is 3-4 less intense over the electric field that would form in the absence of the body portion.

18. A method of CVD reactor operation comprising:
(a) providing the CVD reactor of claim 1;
(b) feeding a carbon bearing reactive gas into the plasma zone; and
(c) concurrent with step (b), feeding microwaves into the resonant cavity thereby forming in the plasma zone a plasma that causes a diamond film to form in the plasma zone.

19. The method of claim 18, further including:
(d) concurrent with step (c), evacuating the plasma zone to a pressure lower than the upper zone.

20. The method of claim 18, wherein the diamond film form on a substrate disposed on a side of the plasma zone opposite the antenna.
